(19) United States
(12) Patent Application Publication
(10) Pub. No.: US 2025/0258236 A1
(43) Pub. Date: Aug. 14, 2025

(54) VOLTAGE DETECTION DEVICE AND VOLTAGE DETECTION METHOD

(71) Applicant: ROHM Co., Ltd., Kyoto (JP)

(72) Inventors: BINH AN NGUYEN, Yokohama (JP); Hiroaki SANO, Yokohama (JP)

(73) Assignee: ROHM Co., Ltd., Kyoto (JP)

(21) Appl. No.: 19/046,484

(22) Filed: Feb. 5, 2025

(30) Foreign Application Priority Data
Feb. 9, 2024 (JP) 2024-018981

(51) Int. Cl. G01R 31/3835; H03M 1/12

(52) U.S. Cl. CPC G01R 31/3835; H03M 1/129

(57) ABSTRACT

A voltage detection device, measuring a voltage of a battery by using an analog-to-digital converter (ADC). The voltage detection device includes: a level shift unit, shifting a voltage level of a voltage signal output from the battery to a median of a measurement range of the ADC; an amplification unit, amplifying the voltage signal in which the voltage level is shifted by the level shift unit; the ADC, measuring the voltage signal amplified by the amplification unit, and outputting a digital sample signal in accordance with the voltage signal; and a derivation unit, deriving a voltage value of a voltage of the battery based on the sample signal output from the ADC.

### CROSS-REFERENCE TO RELATED APPLICATION

This application claims the priority benefit of Japan application serial no. 2024-018981, filed on Feb. 9, 2024. The entirety of the above-mentioned patent application is hereby incorporated by reference herein and made a part of this specification.

### BACKGROUND

### Technical Field

The disclosure relates to a voltage detection device and a voltage detection method.

### Description of Related Art

A technology for detecting the output voltage of a battery by using an analog-to-digital converter (ADC) is known (see, for example, Japanese Patent Application Laid-open No. 2002-221544). The ADC serves for converting an analog voltage into a digital value. By connecting the output terminal of the battery to the input terminal of the ADC, the output voltage of the battery can be measured as a digital value.

### SUMMARY

Changes of the output voltage of a battery include large changes over long periods and small changes over short periods. For example, in the changes in correspondence with the charge and discharge of the battery, the voltage changes so that the voltage decreases as the discharge time increases. Also, for example, in the changes in correspondence with fluctuations in the load connected to the battery, the voltage changes to fluctuate (oscillate) up and down in a relatively short period.

However, detecting both changes of the output voltage of the battery over long and short periods of time has not been easy, as such detection depends on the measurement range of the ADC used for detection, etc.

Provided is a voltage detection device and a voltage detection method capable of accurately detecting both changes of the output voltage of the battery over long and short periods of time.

To achieve the objective, a voltage detection device of the disclosure measures a voltage of a battery by using an analog-to-digital converter (ADC). The voltage detection device includes: a level shift unit, shifting a voltage level of a voltage signal output from the battery to a median of a measurement range of the ADC; an amplification unit, amplifying the voltage signal in which the voltage level is shifted by the level shift unit; the ADC, measuring the voltage signal amplified by the amplification unit, and outputting a digital sample signal in accordance with the voltage signal; and a derivation unit, deriving a voltage value of a voltage of the battery based on the sample signal output from the ADC.

Also, to achieve the objective, in a voltage detection method according to the disclosure, a processor included in a voltage detection device that measures a voltage of a battery by using an analog-to-digital converter (ADC) is configured to: shift, by using a level shift unit, a voltage level of a voltage signal output from the battery to a median of a measurement range of the ADC; amplify, by using an amplification unit, the voltage signal in which the voltage level is shifted by the level shift unit; measure, by using the ADC, the voltage signal amplified by the amplification unit, and outputting a digital sample signal in accordance with the voltage signal; and derive a voltage value of a voltage of the battery based on the sample signal output from the ADC.

### BRIEF DESCRIPTION OF THE DRAWINGS

FIG. 1 is a block diagram illustrating an example of a configuration of a voltage detection device according to a first embodiment.

FIG. 2 is a diagram illustrating changes of a voltage output from a battery.

FIG. 3 is a circuit diagram illustrating an example of a hardware configuration of a microcontroller.

FIG. 4 is a diagram illustrating the function of a multiplication-and-division unit.

FIG. 5 is a configuration diagram illustrating an example of a configuration of the multiplication-and-division unit.

FIG. 6 is a circuit diagram illustrating an example of the configuration of a logarithmic conversion circuit.

FIG. 7 is a circuit diagram illustrating an example of the configuration of an addition circuit.

FIG. 8 is a circuit diagram illustrating an example of the configuration of a subtraction circuit.

FIG. 9 is a circuit diagram illustrating an example of the configuration of an inverse logarithmic conversion circuit.

FIG. 10 is a diagram for describing the operation of an amplification unit.

FIG. 11 is a circuit diagram illustrating an example of the configuration of the amplification unit.

FIG. 12 is a flowchart illustrating an example of the flow of a measurement process according to the first embodiment.

FIG. 13 is a flowchart illustrating an example of the flow of the multiplication-and-division unit.

FIG. 14 is a flowchart illustrating an example of the flow of an amplification unit adjustment process.

FIG. 15 is a flowchart illustrating an example of the flow of the inverse calculation process of a sample value based on the parameters of the amplification unit.

FIG. 16 is a flowchart illustrating an example of the flow of the inverse calculation process of a sample value based on the parameters of the multiplication-and-division unit.

FIG. 17 is a block diagram illustrating an example of a voltage detection device according to a second embodiment.

FIG. 18 is a diagram for describing the operation of a subtraction unit.

FIG. 19 is a circuit diagram illustrating an example of the configuration of the subtraction unit.

FIG. 20 is a circuit diagram illustrating an example of the configuration of the amplification unit.

FIG. 21 is a flowchart illustrating an example of the flow of a measurement process according to the second embodiment.

FIG. 22 is a flowchart illustrating an example of the flow of a subtraction unit adjustment process.

### DETAILED DESCRIPTION

According to the disclosure, both changes of the output voltage of the battery over long and short periods of time can be accurately detected.

The embodiments of the disclosure will be described in detail below with reference to the drawings. It should be noted that the following embodiments do not limit the technology of the disclosure.

### First Embodiment

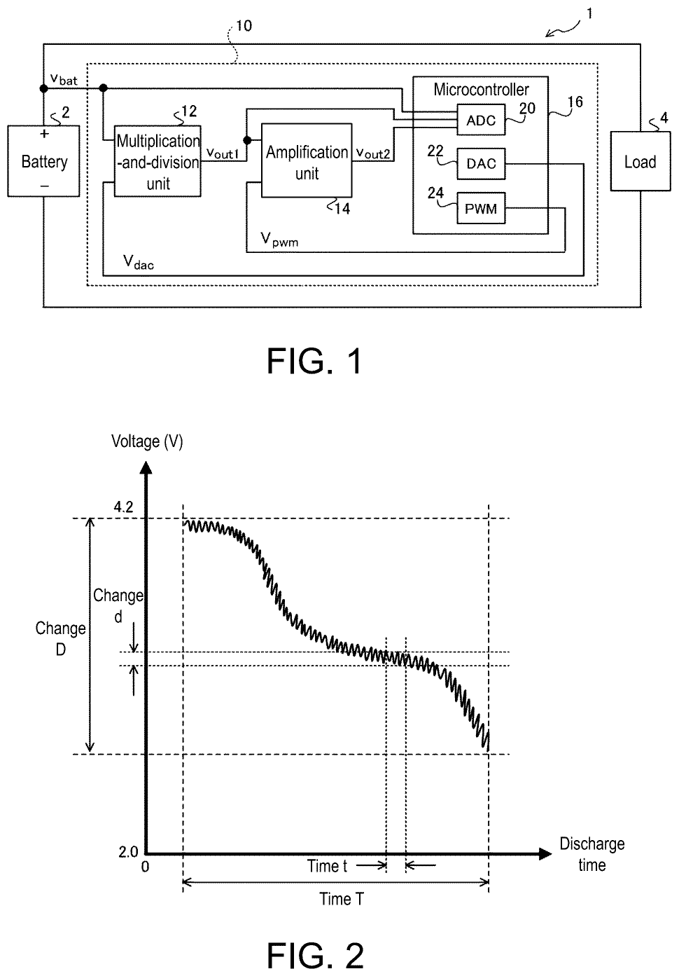

First, the configuration of a voltage detection device of the embodiment will be described. FIG. 1 illustrates a block diagram representing an example of the configuration of a voltage detection device 10 of the embodiment. As shown in FIG. 1, the battery 2, which is a detection target of the voltage detection device 10 of the embodiment, is connected to a load 4 and supplies voltage to the load 4. The load 4 is driven by receiving the voltage supplied from the battery 2. Examples of the load 4 may include various circuits and semiconductor devices.

The battery 2 of the embodiment is rechargeable, and can be used repeatedly by charging. Referring to FIG. 2, the change of a voltage (output voltage) v_{bat} output from the battery 2 will be described. The voltage v_{bat} output from the battery 2 changes significantly over a long period of time (see time T in FIG. 2) in response to charge and discharge (see change D in FIG. 2). Specifically, the longer the discharge time, the smaller the voltage v_{bat} becomes. In addition, the voltage v_{bat} output from the battery 2 changes slightly (see change d in FIG. 2) in a relatively short time (see time t in FIG. 2) in accordance with the fluctuations of the load 4. Specifically, in accordance with the fluctuations of the load 4, the voltage v_{bat} fluctuates to the upper limit in a short period of time.

The voltage detection device 10 detects the voltage v_{bat} of the battery 2 that changes as described above. Specifically, the voltage detection device 10 detects a voltage signal corresponding to the voltage v_{bat} output from the battery 2 and measures the voltage value thereof. Here, the voltage signal output from the battery 2, etc., may be simply referred to as “voltage”. Also, the voltage output from various circuits, etc., may be referred to as “output voltage”.

As shown in FIG. 1, the voltage detection device 10 of the embodiment includes a multiplication-and-division unit 12, an amplification unit 14, and a microcontroller 16.

The microcontroller 16 includes an analog-to-digital converter (ADC) 20, a digital-to-analog converter (DAC) 22, and a pulse width modulator (PWM) 24, and has a function of controlling the operation of detecting the voltage of the battery 2 by using the voltage detection device 10.

The ADC 20 is connected to the positive (+) side of the battery 2, and the voltage output from the battery 2 is received by the ADC 20. The ADC 20 is also connected to the multiplication-and-division unit 12. Furthermore, the ADC 20 is connected to the amplification unit 14 and samples an output voltage vₒᵤₜ₂ output from the amplification unit 14. As an example, in the embodiment, an ADC 20 with a measurement range of 5V is used.

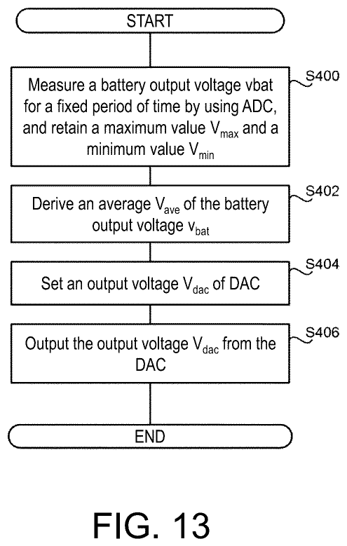

The DAC 22 is connected to the multiplication-and-division unit 12 and has a function of controlling an output voltage vₒᵤₜ₁ output from the multiplication-and-division unit 12 by using an output voltage V_{dac} output from the DAC 22 (details in this regard will be described later). The output voltage V_{dac} of the DAC 22 is set by a multiplication-and-division unit adjustment process (see FIG. 13) to be described in detail later.

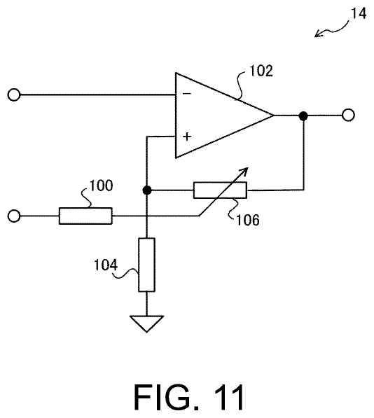

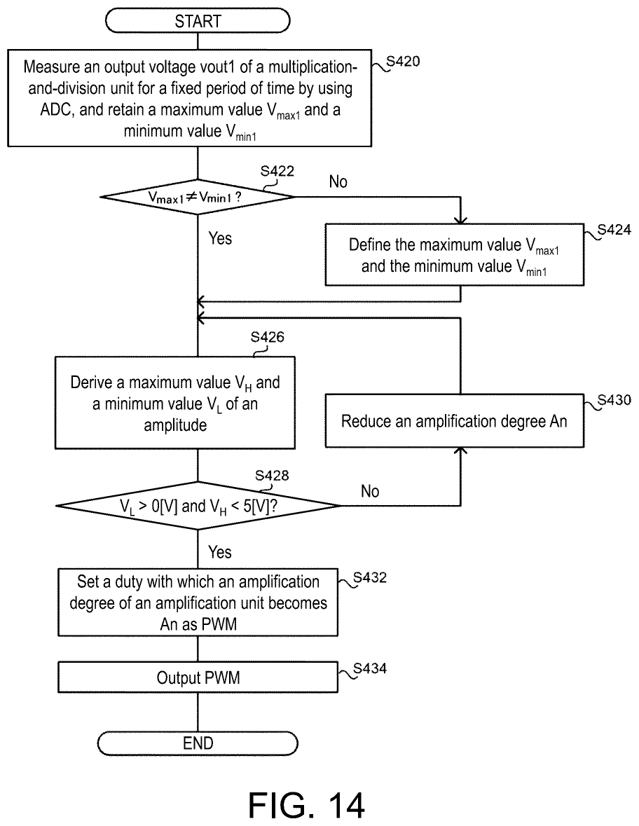

The PWM 24 is connected to the amplification unit 14 and has a function of controlling a resistance value Rᵥₐᵣ of a variable resistor 106 (see FIG. 11) of the amplification unit 14, which will be described in detail later. Specifically, the resistance value Rᵥₐᵣ of the variable resistor 106 of the amplification unit 14 is controlled by an average voltage V_{pwm} output from the PWM 24. The average voltage V_{pwm} of the PWM 24 is set by the amplification unit baking process (see FIG. 14) to be described in detail later.

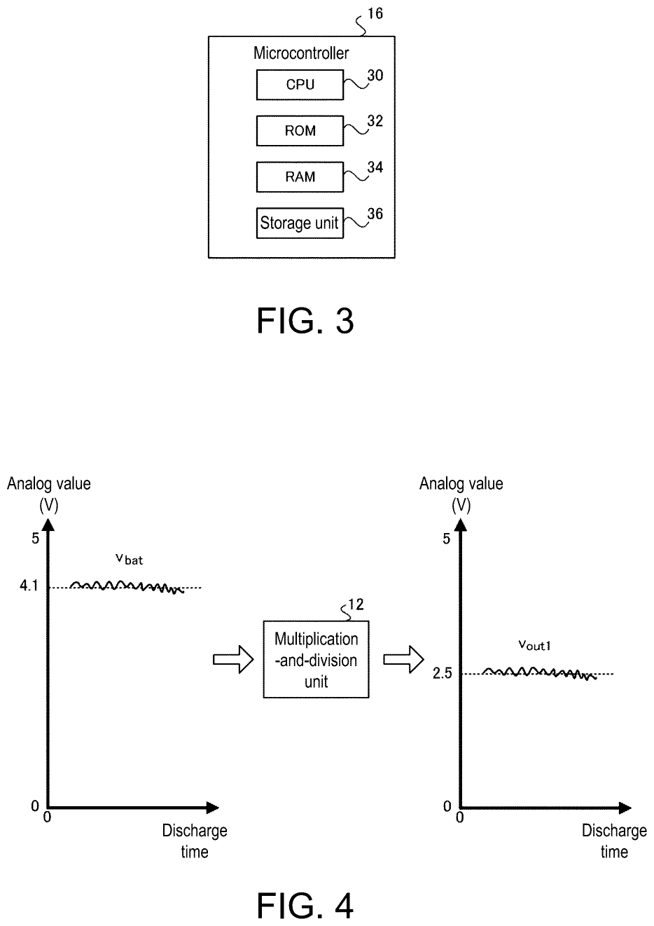

Such microcontroller 16 is, for example, as shown in FIG. 3. The microcontroller 16 includes hardware components such as a central processing unit (CPU) 30, a read-only memory (ROM) 32, a random access memory (RAM) 34, and a storage unit 36. The CPU 30, the ROM 32, the RAM 34, and the storage unit 36 are connected to enable transmission/reception of various information via buses (not shown) such as system buses, control buses. The CPU 30 is an example of a processor that controls the microcontroller 16. The CPU 30 of the embodiment is an example of the derivation unit of the disclosure. The ROM 32 stores various programs in advance, including programs for performing the measurement process (details described later) to measure the output voltage v_{bat} of the battery 2, which are executed by the CPU 30. The RAM 34 temporarily stores various data. The storage unit 36 stores various information such as the measurement value of the output voltage v_{bat} of the battery 2. As the storage unit 36, various types of memories, etc., can be used, for example. The program for performing the measurement process may be stored in the storage unit 36. The storage unit 36 may be provided other than the inside of the microcontroller 16, that is, external to the microcontroller 16. In this case, the measurement value is stored in the storage unit 36 by using the microcontroller 16 transmitting the measurement value obtained through measurement to the storage unit 36 provided externally.

The multiplication-and-division unit 12 is a circuit that performs multiplication or division on the output voltage v_{bat}, which is the analog voltage output from the battery 2. Logarithmic conversion is performed on the input voltage, and voltages that are logarithmically converted are added or subtracted. Subsequently, by performing inverse logarithmic conversion on the voltage obtained through addition or subtraction, the result of performing multiplication or division on the original voltage can be obtained.

The multiplication-and-division unit 12 of the embodiment has a function to shift the level of the output voltage output from the battery 2. Specifically, the multiplication-and-division unit 12 has a function to shift the voltage level of the voltage signal output from the battery 2 to the median of the measurement range of the ADC 20. More specifically, as shown in FIG. 4, the multiplication-and-division unit 12 outputs the output voltage vₒᵤₜ₁ in which the level (voltage value) of the output voltage v_{bat} is shifted, such that the average Vₐᵥₑ (4.1V in FIG. 4) of the output voltage v_{bat} output from the battery 2 over a predetermined discharge time becomes the median (2.5V in FIG. 4) of the measurement range of the ADC 20. The multiplication-and-division unit 12 of the embodiment is an example of the level shift unit of the disclosure.

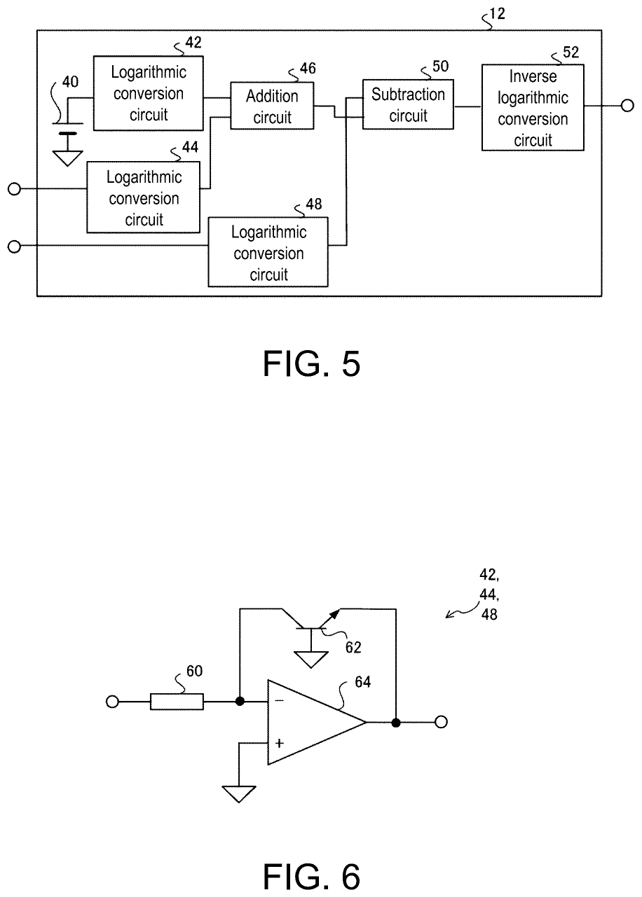

The specific configuration of the multiplication-and-division unit 12 of the embodiment is described. As shown in FIG. 5, the multiplication-and-division unit 12 of the embodiment includes a constant voltage source 40, a logarithmic conversion circuit 42, a logarithmic conversion circuit 44, an addition circuit 46, a logarithmic conversion circuit 48, a subtraction unit 50, and an inverse logarithmic conversion circuit 52.

The constant voltage source 40 serves to supply the voltage received by the logarithmic conversion circuit 42, and outputs a voltage with a voltage value same as the median of the measurement range of the ADC 20 to the logarithmic conversion circuit 42. As mentioned above, in the embodiment, an ADC 20 with a measurement range of 5V is used. In such case, the constant voltage source 40 is set to supply a power supply voltage V_{DD} of 2.5V. In the case where the voltage value of the constant voltage source 40 is greater than the median of the measurement range of the ADC 20, the voltage value can be divided by a resistor or other elements, so that the voltage value after division becomes the median of the measurement range of the ADC 20, and the power supply voltage V_{DD} after division can be supplied.

The logarithmic conversion circuits 42, 44, and 48 have similar configurations. FIG. 6 illustrates an example of the configuration of the logarithmic conversion circuit 42, 44, and 48. The logarithmic conversion circuit 42, 44, and 48 include a resistor 60, an NPN-type transistor 62, and an operational amplifier 64. The input terminal on the positive side of the operational amplifier 64 is connected to ground. In addition, an end of the resistor 60 is connected to the input terminal on the negative side of the operational amplifier 64. As an example, in the embodiment, the resistance value of the resistor 60 is set to 25 kΩ. In the NPN-type transistor 62, the collector is connected to the input terminal on the negative side of the operational amplifier 64, and the emitter is connected to the output terminal of the operational amplifier 64.

In the case of the logarithmic conversion circuit 42, the other end of the resistor 60 is connected to the constant voltage source 40. In addition, the output terminal of the operational amplifier 64 is connected to the addition circuit 46. On the other hand, in the case of the logarithmic conversion circuit 44, the other end of the resistor 60 is connected to the positive side of the battery 2. In addition, the output terminal of the operational amplifier 64 is connected to the addition circuit 46. Furthermore, in the case of the logarithmic conversion circuit 48, the other end of the resistor 60 is connected to the DAC 22. In addition, the output terminal of the operational amplifier 64 is connected to the subtraction unit 50.

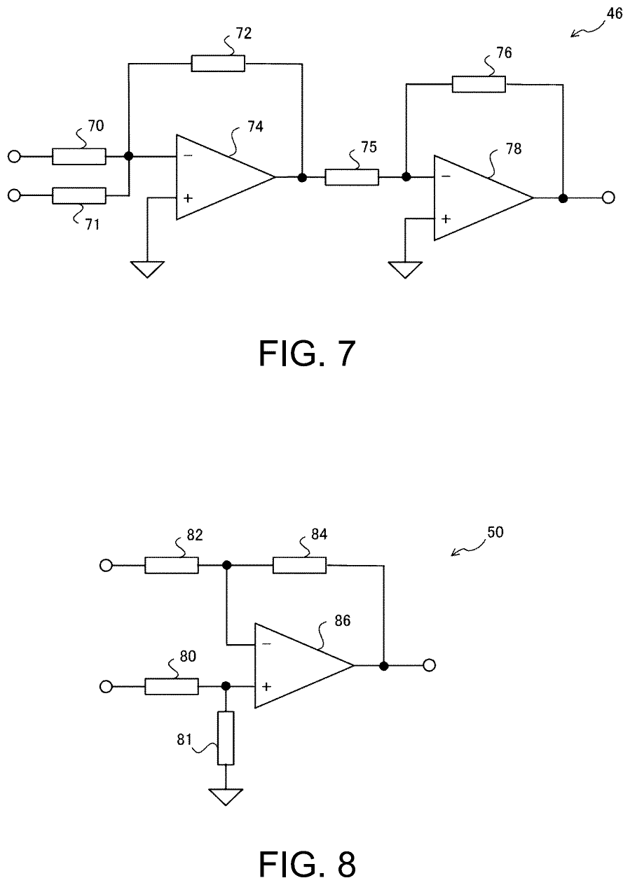

The addition circuit 46, as shown in FIG. 7, includes resistors 70, 71, 72, 75, 76, and operational amplifiers 74, 78. In the embodiment, the resistance values of resistors 70, 71, 72, 75, 76 are set to be identical. As an example, in the embodiment, the resistance value is set to 10 kΩ.

The input terminal on the positive side of the operational amplifier 74 is connected to ground. In addition, an end of the resistor 70, in which the other end is connected to the logarithmic conversion circuit 42, is connected to the input terminal on the negative side of the operational amplifier 74. In addition, an end of the resistor 71, in which the other end is connected to the logarithmic conversion circuit 44, is connected to the input terminal on the negative side of the operational amplifier 74. Furthermore, the resistor 72 is connected between the input terminal on the negative side and the output terminal of the operational amplifier 74. The output terminal of the operational amplifier 74 is connected to the input terminal on the negative side of the operational amplifier 78 through the resistor 75. The input terminal on the positive side of the operational amplifier 78 is connected to ground. In addition, the resistor 76 is connected between the input terminal on the negative side and the output terminal of the operational amplifier 78. The output terminal of the operational amplifier 78 is connected to the subtraction unit 50.

The subtraction unit 50, as shown in FIG. 8, includes resistors 80, 81, 82, 84, and an operational amplifier 86. In the embodiment, the resistance values of the resistors 80, 81, 82, 84 are set to be identical, and are also identical to those of the resistors 70, 71, 72, 75, 76 in the addition circuit 46. As an example, in the embodiment, the resistance value is set to 10 kΩ. The input terminal on the positive side of the operational amplifier 86 is connected to ground through the resistor 81. In addition, an end of the resistor 80, in which the other end is connected to the logarithmic conversion circuit 48, is connected to the input terminal on the positive side of the operational amplifier 86. On the other hand, an end of the resistor 82, in which the other end is connected to the addition circuit 46, is connected to the input terminal on the negative side of the operational amplifier 86. The resistor 84 is connected between the input terminal on the negative side and the output terminal of the operational amplifier 86. The output terminal of the operational amplifier 86 is connected to the inverse logarithmic conversion circuit 52.

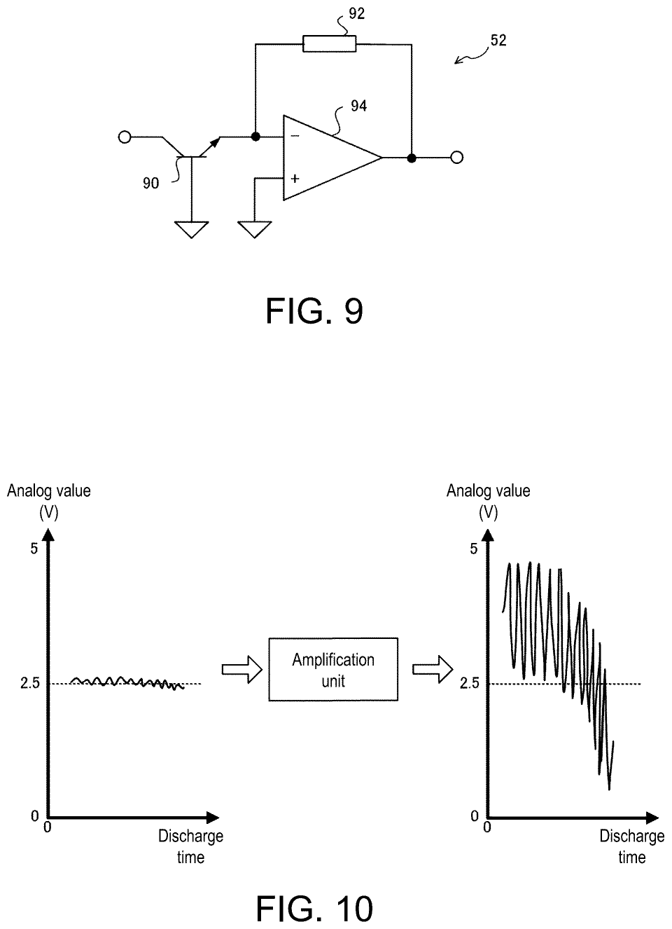

The inverse logarithmic conversion circuit 52, as shown in FIG. 9, includes an NPN-type transistor 90, a resistor 92, and an operational amplifier 94. The input terminal on the positive side of the operational amplifier 94 is connected to ground. In addition, the emitter of the NPN-type transistor 90 is connected to the input terminal on the negative side of the operational amplifier 94. The collector of the NPN-type transistor 90 is connected to the subtraction unit 50. In addition, the resistor 92 is connected between the input terminal on the negative side and the output terminal of the operational amplifier 94. The resistance value of the resistor 92 is set to be identical to the resistance values of the logarithmic conversion circuits 42, 44, 48. As an example, in the embodiment, the resistance value of the resistor 92 is set to 25 kΩ. The output terminal of the operational amplifier 94 is output to the amplification unit 14.

The voltage vₒᵤₜ₁ output from the multiplication-and-division unit 12 (inverse logarithmic conversion circuit 52) is received by the amplification unit 14. The output voltage vₒᵤₜ₁ output by the multiplication-and-division unit 12 is derived by using Equation (1) as follows, which utilizes the output voltage v_{bat} of the battery 2, the power supply voltage V_{DD} of the constant voltage source 40, and the output voltage V_{dac} of the DAC 22. It should be noted that Equation (1) is shown for the case where the power supply voltage V_{DD} of the constant voltage source 40 is 2.5V, as mentioned above.

$$[ Formula 1 ]$$

$${v}_{out 1} = {v}_{bat} \times \frac{{V}_{DD}}{{V}_{dac}} = \frac{2.5}{{V}_{dac}} {v}_{bat} \qquad ( 1 )$$

The amplification unit 14 is a circuit that amplifies the amplitude of an analog voltage. In the embodiment, the amplification unit 14 has a variable amplification degree and serves to amplify the voltage vₒᵤₜ₁ output from the multiplication-and-division unit 12. Specifically, as shown in FIG. 10, the amplification unit 14 serves to amplify the amplitude of the changing output voltage v_{bat} output from the battery 2 by amplifying the voltage vₒᵤₜ₁, and output the amplified voltage vₒᵤₜ₂. More specifically, the amplification unit 14 amplifies the voltage vₒᵤₜ₁ so that the voltage vₒᵤₜ₂ within a predetermined discharge time does not exceed the measurement range of the ADC 20, while effectively utilizing the measurement range. The amplification unit 14 in the embodiment is an example of the amplification unit of the disclosure.

In the embodiment, a non-inverting amplification unit is used as the amplification unit 14. FIG. 11 illustrates a circuit diagram of an example of the configuration of the amplification unit 14 in the embodiment. As shown in FIG. 11, the amplification unit 14 in the embodiment includes resistors 100, 104, an operational amplifier 102, and a variable resistor 106. The variable resistor 106 is connected between the input terminal on the positive side and the output terminal of the operational amplifier 102. In the embodiment, a variable resistor whose resistance value can be controlled by using voltage is used as the variable resistor 106. Specifically, an analog photocoupler using a cadmium sulfide (CdS) cell is used as the variable resistor 106.

In addition, the input terminal on the positive side of the operational amplifier 102 is connected to ground through the resistor 104. The resistance value of the resistor 104 is set to be the same as the resistance value of the analog photocoupler at the time when the voltage (5V in the embodiment) of the full range of the ADC 20 is received by the variable resistor 106 as an analog photocoupler. Due to the properties of the analog photocoupler, the measurement values may differ. Therefore, the resistance value of the resistor 104 is determined after measuring the properties of the analog photocoupler. The resistor 100 is connected to the PWM 24 and serves as a resistor to prevent overcurrent from flowing into the light-emitting diode (LED) used in the analog photocoupler of the variable resistor 106. The resistance value of the resistor 100 is determined according to the specification of the analog photocoupler. On the other hand, the input terminal on the negative side of the operational amplifier 102 is connected to the inverse logarithmic conversion circuit 52 of the multiplication-and-division unit 12.

An amplification degree A of the amplification unit 14 is determined by a resistance value R of the resistor 104 and the resistance value Rᵥₐᵣ of the variable resistor 106, as shown in Equation (2) in the following. As mentioned above, the resistance value Rᵥₐᵣ of the variable resistor 106 is controlled by the average voltage V_{pwm} output from the PWM 24 of the microcontroller 16.

$$[ Formula 2 ]$$

$$A = 1 + \frac{{R}_{var}}{R} \qquad ( 2 )$$

The output voltage vₒᵤₜ₂ output from the amplification unit 14 is received by the ADC 20 of the microcontroller 16 and sampled by the ADC 20. According to Equations (1) and (2) above, the output voltage vₒᵤₜ₂ output from the amplification unit 14 when the output voltage vₒᵤₜ₁ of the multiplication-and-division unit 12 is received by the amplification unit 14 is calculated by Equation (3) as follows:

$$[ Formula 3 ]$$

$${v}_{out 2} = A \times {v}_{out 1} = ( 1 + \frac{{R}_{var}}{R} ) \frac{2.5}{{V}_{dac}} {v}_{bat} \qquad ( 3 )$$

Then, the measurement process for measuring the output voltage v_{bat} of the battery 2 by using the voltage detection device 10 of the embodiment will be described. In the embodiment, as preliminary preparation before performing the measurement process, the microcontroller 16 retains information representing the correspondence relationship of the value of the amplification degree of the amplification unit 14 with respect to the percentage of the duty of the PWM 24. The information representing the correspondence relationship can be obtained by deriving the amplification degree An through actually inputting the average voltage V_{pwm} of the PWM 24 to the variable resistor 106 (photocoupler) of the amplification unit 14 while varying the duty of the PWM 24, and measuring the resistance value Rᵥₐᵣ of the photocoupler at this time. In the embodiment, the information representing the correspondence relationship obtained by actually measuring the resistance value Rᵥₐᵣ is stored in advance in the storage unit 36 of the microcontroller 16.

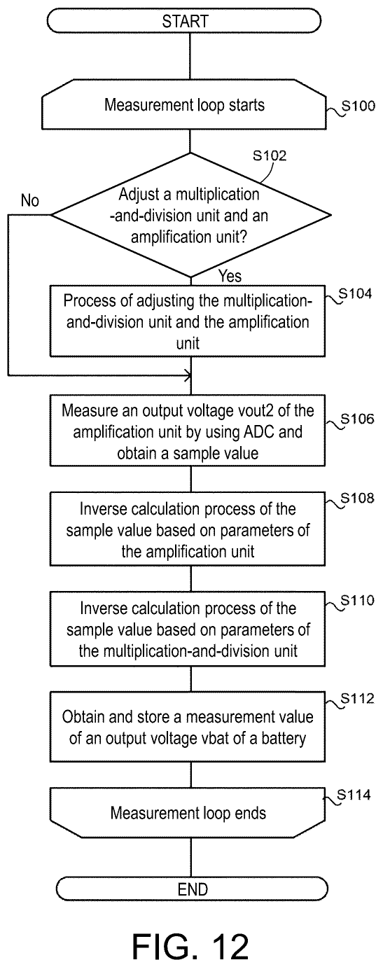

FIG. 12 illustrates a flowchart representing an example of the flow of the measurement process executed by the microcontroller 16 of the voltage detection device 10. In the embodiment, the measurement process shown in FIG. 12 is executed by the CPU 30 of the microcontroller 16 executing a program (not shown) stored in the ROM 32.

As shown in FIG. 12, the measurement of the output voltage v_{bat} of the battery 2 is performed by repeating the processes of Steps S100 to S114.

As shown in FIG. 12, first, in Step S100, a measurement loop is started.

Then, in Step S102, the CPU 30 determines whether to adjust the multiplication-and-division unit 12 and the amplification unit 14. Regarding whether to adjust the multiplication-and-division unit 12 and the amplification unit 14, an arbitrary condition, such as the elapsed time from the previous adjustment, the fluctuation of the output voltage v_{bat} of the battery 2, etc., may be set, and the CPU 30 may perform the determination based on the set condition. If the multiplication-and-division unit 12 and the amplification unit 14 are not to be adjusted, the process of Step S102 results in a negative determination, and the flow proceeds to Step S106. On the other hand, if the multiplication-and-division unit 12 and the amplification unit 14 are to be adjusted, the determination in Step S102 results in a positive determination, and the flow proceeds to Step S104.

In Step S104, the CPU 30 executes the process of adjusting the multiplication-and-division unit 12 and the amplification unit 14, the details of which will be described later.

Then, in Step S106, the CPU 30 measures the output voltage vₒᵤₜ₂ of the amplification unit 14 by using the ADC 20 and obtains a sampling value. As mentioned above, the output voltage vₒᵤₜ₂ of the amplification unit 14 is the result of the output voltage v_{bat} of the battery 2 being changed through the multiplication-and-division unit 12 and the amplification unit 14.

Then, in Step S108, the CPU 30 performs an inverse calculation process (details described later) of inversely calculating the sample value of the output voltage vₒᵤₜ₂ based on the parameters of the amplification unit 14, and converts the inversely calculated value to the voltage value before being received by the amplification unit 14

Then, in Step S110, the CPU 30 performs the inverse calculation process (details described later) to inversely calculate the sample value obtained in Step S108 based on the parameters of the multiplication-and-division unit 12, and converts the inversely calculated value to the voltage value before being received by the multiplication-and-division unit 12.

Then, in Step S112, the CPU 30 obtains a measurement value (digital value) of the output voltage v_{bat} of the battery 2 and stores the measurement value in the storage unit 36.

By repeating (looping) the processes of Steps S102 to S112, multiple measurement values of the output voltage v_{bat} of the battery 2 are obtained.

In the case where the termination condition is satisfied, in Step S114, the CPU 30 terminates the measurement loop. When the process of Step S114 is completed, the measurement process shown in FIG. 12 is ended.

Furthermore, the adjustment process of the multiplication-and-division unit 12 and the amplification unit 14, which is executed in Step S104 of the measurement process of FIG. 12, will be described. The adjustment process includes two processes, that is, a multiplication-and-division unit adjustment process for adjusting the multiplication-and-division unit 12, and an amplification unit adjustment process for adjusting the amplification unit 14.

First, the multiplication-and-division unit adjustment process for adjusting the multiplication-and-division unit 12 will be described. FIG. 13 shows a flowchart representing an example of the flow of the multiplication-and-division unit adjustment process executed by the microcontroller 16 of the voltage detection device 10.

In Step S400 of FIG. 13, the CPU 30 measures the output voltage v_{bat} of the battery 2 for a fixed period of time, and obtains and retains a maximum value Vₘₐₓ and a minimum value Vₘᵢₙ of the output voltage v_{bat} as digital values.

Then, in Step S402, the CPU 30 derives the average Vₐᵥₑ of the output voltage v_{bat} of the battery 2. In the embodiment, the CPU 30 derives the average Vₐᵥₑ by using Equation (4) as follows to calculate the average of the maximum value Vₘₐₓ and the minimum value Vₘᵢₙ of the output voltage v_{bat}.

$$[ Formula 4 ]$$

$${V}_{ave} = \frac{{V}_{max} + {V}_{min}}{2} \qquad ( 4 )$$

Then, in Step S404, the CPU 30 sets the output voltage V_{dac} of the DAC 22. In the embodiment, the output voltage V_{dac} of the DAC 22 is set to be the same as the average Vₐᵥₑ of the output voltage v_{bat} of the battery 2.

Then, in Step S406, the CPU 30 starts the output of the output voltage V_{dac} from the DAC 22. When the process of Step S406 is completed, the multiplication-and-division unit adjustment process shown in FIG. 13 is finished.

Then, the amplification unit adjustment process for adjusting the amplification unit 14 will be described. FIG. 14 shows a flowchart representing an example of the flow of the amplification unit adjustment process executed by the microcontroller 16 of the voltage detection device 10.

In Step S420 of FIG. 14, the CPU 30 measures the output voltage vₒᵤₜ₁ of the multiplication-and-division unit 12 for a fixed period of time, obtains and retains the maximum value Vₘₐₓ₁ and the minimum value Vₘᵢₙ₁ of the output voltage vₒᵤₜ₁ as digital values.

Then, in Step S422, the CPU 30 determines whether the maximum value Vₘₐₓ₁ and the minimum value Vₘᵢₙ₁ are different values (Vₘₐₓ₁·Vₘᵢₙ₁). In the case where the maximum value Vₘₐₓ₁ and the minimum value Vₘᵢₙ₁ are not different values, the determination in Step S422 results in a negative determination, and the flow proceeds to Step S424.

In Step S424, the CPU 30 defines the maximum value Vₘₐₓ₁ and the minimum value Vₘᵢₙ₁ to be different values, and then proceeds to Step S426. Specifically, the CPU 30 defines the maximum value Vₘₐₓ₁ by using Equation (5) as follows, and defines the minimum value Vₘᵢₙ₁ by using Equation (6) as follows. For “x” in Equations (5) and (6) below, the minimum value that can be expressed as a digital value by the ADC 20 is used. The value of “x” is determined in advance according to the expected variation amount in the output voltage vₒᵤₜ₁ of the multiplication-and-division unit 12.

$$[ Formula 5 ]$$

$${V}_{max 1} = {V}_{max 1} + x \qquad ( 5 )$$

$${V}_{min 1} = {V}_{min 1} - x \qquad ( 6 )$$

Meanwhile, in the case where the maximum value Vₘₐₓ₁ and the minimum value Vₘᵢₙ₁ are different values, the determination in Step S422 results in a positive determination, and the flow proceeds to Step S426. In step S426, the CPU 30 derives a maximum value V_{H} and a minimum value V_{L} of the amplitude when amplified by the amplification degree An of the amplification unit 14, which has been obtained in advance during preparation. Specifically, the CPU 30 derives the maximum value V_{H} of the amplitude by using Equation (7) as follows, and derives the minimum value V_{L} of the amplitude by using Equation (8) as follows.

$$[ Formula 6 ]$$

$${V}_{H} = {V}_{max 1} + ( {V}_{max 1} - {V}_{min 1} ) \times ( \frac{{A}_{n}}{2} ) \qquad ( 7 )$$

$${V}_{L} = {V}_{min 1} + ( {V}_{max 1} - {V}_{min 1} ) \times ( \frac{{A}_{n}}{2} ) \qquad ( 8 )$$

Then, in Step S428, the CPU 30 determines whether the amplitude when amplified by the amplification degree An of the amplification unit 14 fits within the measurement range of the ADC 20. In the embodiment, since the measurement range of the ADC 20 is 0V to 5V, the CPU 30 specifically determines whether the condition that the minimum value V_{L} of the amplitude is greater than 0V (V_{L}>0) and the maximum value V_{H} of the amplitude is less than 5V (V_{H}<5) is satisfied. If the condition is not satisfied, the determination in Step S428 results in a negative determination, and the flow proceeds to Step S430. In this case, since the output voltage vₒᵤₜ₂ of the amplification unit 14 amplified by the set amplification degree An does not fit within the measurement range of the ADC 20, in Step S430, the CPU 30 changes the amplification degree An from the current value to a smaller value, and then returns to Step S426. As a result, the process of Step S426 is performed again with the amplification degree An being reset to a smaller value.

On the other hand, in the case where the minimum value V_{L} of the amplitude derived in Step S426 is greater than 0V and the maximum value V_{H} of the amplitude is less than 5V, the determination in Step S428 results in a positive determination, and the flow proceeds to Step S432.

Then, in Step S432, the CPU 30 derives the duty of the PWM 24 corresponding to the amplification degree An currently set in the amplification unit 14 from the information representing the correspondence relationship described above, and sets the duty in the PWM 24.

Then, in Step S434, the CPU 30 starts signal output from the PWM 24. As described above, the average voltage V_{pwm} of the output voltage output from the PWM 24 changes the resistance value of the variable resistor 106 (photocoupler) of the amplification unit 14, and the amplification unit with the amplification degree An that satisfies the condition is realized. When the process of Step S434 is completed, the amplification unit adjustment process shown in FIG. 14 is completed.

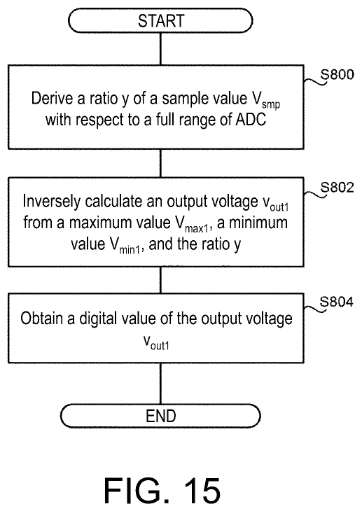

Furthermore, the inverse calculation process of the sample value based on the parameters of the amplification unit 14, which is executed in Step S108 of the measurement process in FIG. 12, will be described. FIG. 15 shows a flowchart representing an example of the flow of the inverse calculation process of the sample value based on the parameters of the amplification unit 14, executed by the microcontroller 16 of the voltage detection device 10.

In Step S800 of FIG. 15, the CPU 30 derives a ratio y of a sample value Vₛₘₚ obtained by the ADC 20 to the full range of the ADC 20. Since the full range of the ADC 20 is 5V, in the embodiment, the CPU 30 derives the ratio y by using Equation (9) as follows.

$$[ Formula 7 ]$$

$$y = \frac{{V}_{smp}}{5} \qquad ( 9 )$$

Then, in Step S802, the CPU 30 inversely calculates the voltage received by the amplification unit 14, that is, the output voltage vₒᵤₜ₁ of the multiplication-and-division unit 12, from the maximum value Vₘₐₓ₁ and the minimum value Vₘᵢₙ₁ of the output voltage vₒᵤₜ₁ of the multiplication-and-division unit 12, and the ratio y derived in Step S800 above. In the embodiment, the CPU 30 inversely calculates the output voltage vₒᵤₜ₁ by using Equation (10) as follows.

$$[ Formula 8 ]$$

$${v}_{out 1} = ( {V}_{max 1} - {V}_{min 1} ) \times y + {V}_{min 1} \qquad ( 10 )$$

Then, in Step S804, the CPU 30 obtains the output voltage vₒᵤₜ₁ derived in Step S802 above as a digital value of the output voltage vₒᵤₜ₁. When the process of Step S804 is completed, the inverse calculation process of the sample value based on the parameters of the amplification unit 14 shown in FIG. 15 is finished.

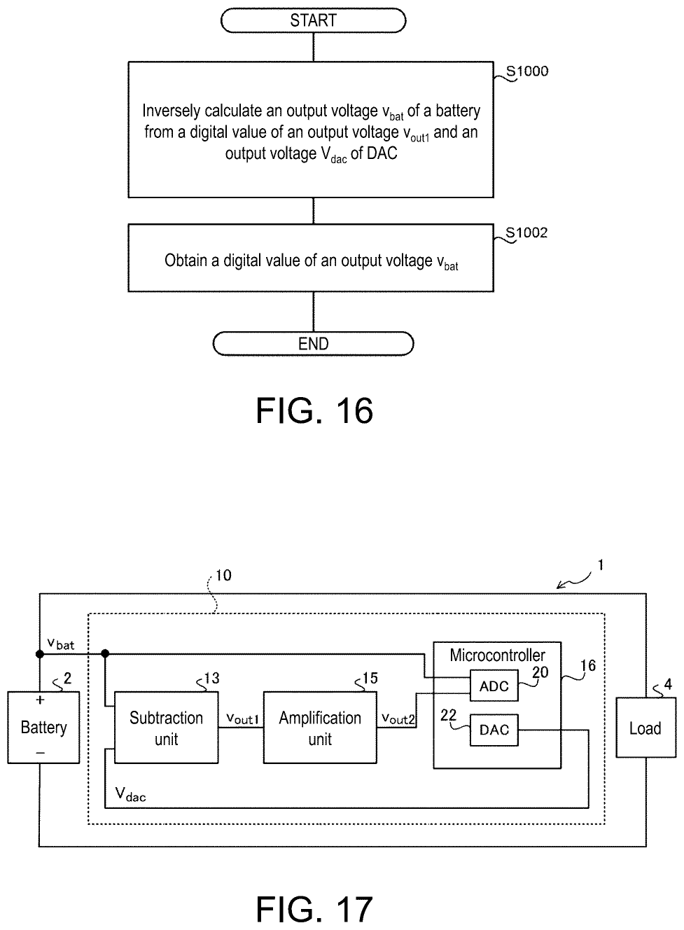

Furthermore, the inverse calculation process of the sample value based on the parameters of the multiplication-and-division unit 12, which is executed in Step S110 of the measurement process in FIG. 12, will be described. FIG. 16 shows a flowchart representing an example of the flow of the inverse calculation process of the sample value based on the parameters of the multiplication-and-division unit 12, executed by the microcontroller 16 of the voltage detection device 10.

In Step S1000 of FIG. 16, the CPU 30 inversely calculates the output voltage v_{bat} of the battery 2 from the digital value of the output voltage Vout of the multiplication-and-division unit 12 obtained by the inverse calculation process of FIG. 15 described above, and the output voltage V_{dac} of the DAC 22. In the embodiment, the CPU 30 inversely calculates the output voltage v_{bat} by using Equation (11) as follows, which is derived from Equation (1) mentioned above.

$$[ Formula 9 ]$$

$${v}_{bat} = {v}_{out 1} \times \frac{{V}_{dac}}{2.5} \qquad ( 11 )$$

Then, in Step S1002, the CPU 30 obtains the output voltage v_{bat} derived in Step S1000 above as a digital value of the output voltage v_{bat}. When the process of Step S1002 is completed, the inverse calculation process of the sample value based on the parameters of the multiplication-and-division unit 12 shown in FIG. 16 is finished.

In this way, in the measurement process shown in FIG. 12, one measurement value of the output voltage v_{bat} of the battery 2 is obtained by the processes of Steps S102 to S112, and measurement values for the number of times of the measurement loop are obtained. With the measurement values for the number of times of the measurement loop, it is possible to accurately detect the changes (amplitude) in the output voltage v_{bat} over a short period of time (see time t in FIG. 2) in response to the fluctuations of the load 4, such as the change d shown in FIG. 2 described above.

Furthermore, in the embodiment, the voltage detection device 10 performs the measurement process and obtains the measurement values of the output voltage v_{bat} of the battery 2 for the number of times of the measurement loop at the respective predetermined timings, such as at the timings corresponding to the elapsed time since the charging the battery 2 is completed, or at timings corresponding to the operating state of the load 4 By connecting the measurement values of the output voltage v_{bat} of the battery 2 for the number of times of the measurement loop obtained at the respective predetermined timings, it is possible to detect changes (see time T in FIG. 2) for a long period of time corresponding to the charge and discharge of the battery 2, such as the change D shown in FIG. 2 described above.

### Second Embodiment

FIG. 17 illustrates a block diagram representing an example of the configuration of a voltage detection device 10 of the embodiment. As shown in FIG. 17, the voltage detection device 10 of the embodiment includes a subtraction unit 13 and an amplification unit 15, which serve as an example of a circuit having two functions, i.e., subtraction and amplification, in place of the multiplication-and-division unit 12 and the amplification unit 14 of the voltage detection device 10 of the first embodiment (see FIG. 1). Additionally, the microcontroller 16 of the embodiment differs from the microcontroller 16 of the first embodiment (see FIG. 1) in that the microcontroller 16 of the embodiment does not include the PWM 24.

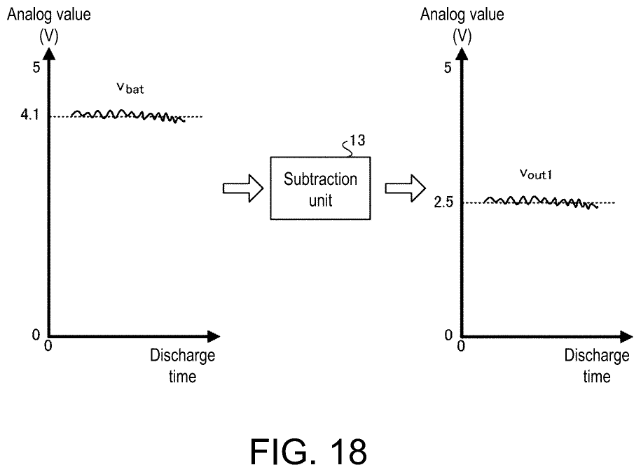

The subtraction unit 13 is a circuit that performs subtraction of the analog voltage output from the battery 2. The subtraction unit 13 of the embodiment has a function of shifting the level of the output voltage v_{bat} output from the battery 2 by subtracting the output voltage V_{dac} of the DAC 22 from the output voltage v_{bat} of the battery 2. Specifically, the subtraction unit 13 has a function of shifting the voltage level of the voltage signal output from the battery 2 to the median of the measurement range of the ADC 20. More specifically, as shown in FIG. 18, the subtraction unit 13 outputs the output voltage vₒᵤₜ₁ with a shifted level (voltage value) of the output voltage v_{bat}, so that the average Vₐᵥₑ (4.1V in FIG. 18) of the output voltage v_{bat} output from the battery 2 for the predetermined discharge time becomes the median of the ADC 20 (2.5V in FIG. 18). The subtraction unit 13 of the embodiment is an example of the level shift unit of the disclosure.

Thus, the output voltage vₒᵤₜ₁ output from the subtraction unit 13 is obtained by Equation (12) as follows.

$$[ Formula 10 ]$$

$${v}_{out} = {v}_{bat} - {v}_{dac} \qquad ( 12 )$$

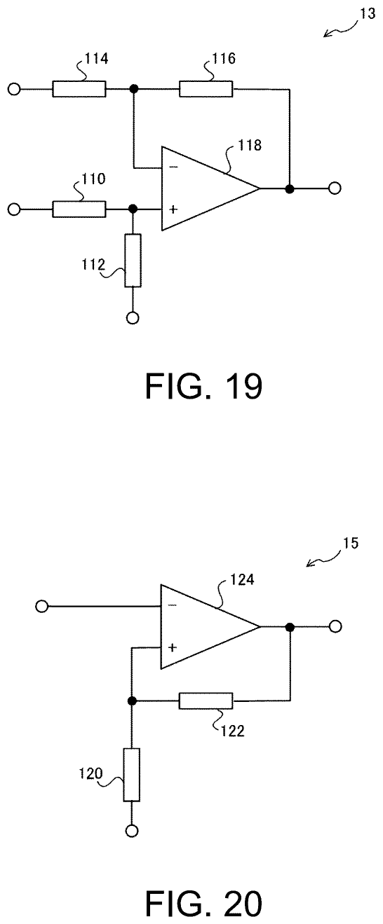

The specific configuration of the subtraction unit 13 of the embodiment is described. FIG. 19 illustrates an example of the configuration of the subtraction unit 13. The subtraction unit 13 includes resistors 110, 112, 114, 116, and an operational amplifier 118. In the embodiment, the resistance values of the resistors 110, 112, 114, 116 are set to be identical. The input terminal on the positive side of the operational amplifier 118 is connected to the DAC 22 through the resistor 110. Additionally, the input terminal on the positive side of the operational amplifier 118 is connected to the reference voltage of the subtraction unit 13 through the resistor 112. In the embodiment, the reference voltage of the subtraction unit 13 is set as the voltage value of the median of the measurement range of the ADC 20. On the other hand, the input terminal on the negative side of the operational amplifier 118 is connected to the positive side of the battery 2 through the resistor 114. In addition, the resistor 116 is connected between the input terminal on the negative side and the output terminal of the operational amplifier 118. Furthermore, the output terminal of the operational amplifier 118 is connected to the amplification unit 15.

The amplification unit 15 is a circuit that amplifies the amplitude of an analog voltage. The amplification unit 15 of the embodiment serves to amplify the voltage vₒᵤₜ₁ output from the subtraction unit 13. Specifically, similar to the amplification unit 14 of the first embodiment, as shown in FIG. 10, the amplification unit 15 serves to amplify the amplitude in which the output voltage v_{bat} output from the battery 2 changes by amplifying the voltage vₒᵤₜ₁ and output the amplified voltage vₒᵤₜ₂. More specifically, the amplification unit 15 amplifies the voltage vₒᵤₜ₁ so that the voltage vₒᵤₜ₂ within a predetermined discharge time does not exceed the measurement range of the ADC 20, while effectively utilizing the measurement range. The amplification unit 15 in the embodiment is an example of the amplification unit of the disclosure. The amplification unit 15 may have a variable amplification degree or a fixed amplification degree.

In the embodiment, a non-inverting amplification unit is used as the amplification unit 15. FIG. 20 illustrates a circuit diagram of an example of the configuration of the amplification unit 15 in the embodiment. As shown in FIG. 20, the amplification unit 15 in the embodiment includes resistors 120, 122, and an operational amplifier 118. The input terminal on the negative side of the operational amplifier 124 is connected to the subtraction unit 13. Meanwhile, the input terminal on the positive side of the operational amplifier 124 is connected to the reference voltage of the amplification unit 15 through the resistor 120. In the embodiment, the reference voltage of the amplification unit 15 is set to the voltage value of the median of the measurement range of the ADC 20. In addition, the resistor 122 is connected between the input terminal on the positive side and the output terminal of the operational amplifier 124.

The output terminal of the operational amplifier 124 is connected to the ADC 20 of the microcontroller 16. The output voltage vₒᵤₜ₂ output from the amplification unit 15 is received by the ADC 20 of the microcontroller 16 and sampled by the ADC 20. The amplification degree of the amplification unit 15 is determined by the resistance value R1 of the resistor 120 and the resistance value R2 of the resistor 122. The output voltage vₒᵤₜ₂ output from the amplification unit 15 is calculated according to Equation (13) in the following.

$$[ Formula 11 ]$$

$${v}_{out 2} = ( 1 + \frac{{R}_{2}}{{R}_{1}} ) {v}_{out 1} \qquad ( 13 )$$

Then, the measurement process for measuring the output voltage v_{bat} of the battery 2 by using the voltage detection device 10 of the embodiment will be described.

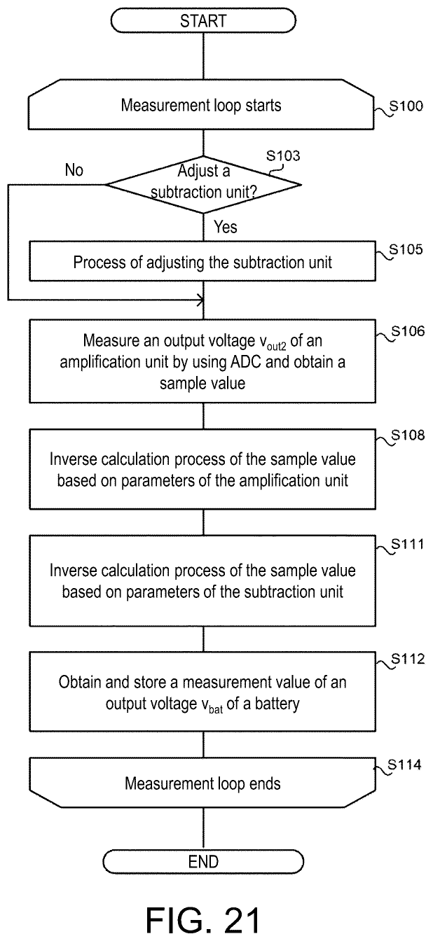

FIG. 21 illustrates a flowchart representing an example of the flow of the measurement process executed by the microcontroller 16 of the voltage detection device 10. The measurement process of the embodiment shown in FIG. 21 differs from the measurement process of the first embodiment (see FIG. 12) in that the measurement process of the embodiment includes the processes of Steps S103 and S105 instead of Steps S102 and S104.

As shown in FIG. 21, in Step S100, when the measurement loop is started, in the next Step S103, the CPU 30 determines whether to adjust the subtraction unit 13. Regarding whether to adjust the subtraction unit 13, an arbitrary condition, such as the elapsed time from the previous adjustment, the fluctuation of the output voltage v_{bat} of the battery 2, etc., may be set, and the CPU 30 may perform the determination based on the set condition. If the subtraction unit 13 is not to be adjusted, the process of Step S103 results in a negative determination, and the flow proceeds to Step S106. Meanwhile, if the subtraction unit 13 is to be adjusted, the process of Step S103 results in a positive determination, and the flow proceeds to Step S105.

In Step S105, the CPU 30 executes the process of adjusting the subtraction unit 13, the details of which will be described later.

Then, in Step S106, the CPU 30 measures the output voltage vₒᵤₜ₂ of the amplification unit 15 by using the ADC 20 and obtains a sampling value, similar to the measurement process of the first embodiment.

Next, in Step S108, the CPU 30 performs an inverse calculation process of inversely calculating the sample value of the output voltage vₒᵤₜ₂ based on the parameters of the amplification unit 15. In the embodiment, the CPU 30 inversely calculates the sample value of the output voltage vₒᵤₜ₂ by performing the inverse calculation process according to Equation (13) above.

Next, in Step S111, the CPU 30 performs an inverse calculation process of inversely calculating the sample value obtained by the process of Step S108 above based on the parameters of the subtraction unit 13, and converts the inversely calculated value to the voltage value before being received by the subtraction unit 13.

Then, in Step S112, the CPU 30 obtains a measurement value (digital value) of the output voltage v_{bat} of the battery 2 and stores the measurement value in the storage unit 36. By repeating (looping) the processes of Steps S103 to S112, multiple measurement values of the output voltage v_{bat} of the battery 2 are obtained.

In the case where the termination condition is satisfied, in Step S114, the CPU 30 terminates the measurement loop. When the process of Step S114 is completed, the measurement process shown in FIG. 21 is ended.

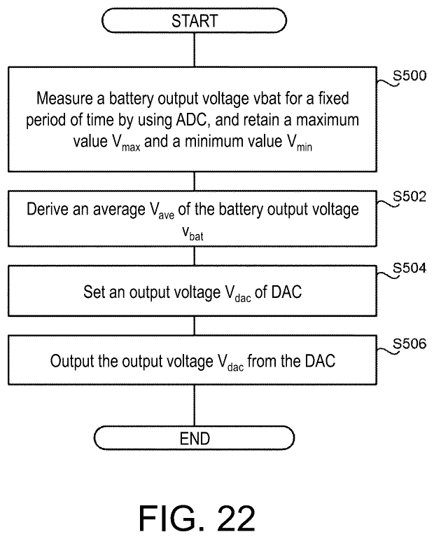

Furthermore, the adjustment process of the subtraction unit 13, which is executed in Step S105 of the measurement process of FIG. 21, will be described. FIG. 22 illustrates a flowchart representing an example of the flow of the subtraction unit adjustment process executed by the microcontroller 16 of the voltage detection device 10. As shown in FIG. 22, the subtraction unit adjustment process of the embodiment is similar to the multiplication-and-division unit adjustment process of the first embodiment (see FIG. 13).

Specifically, in Step S500 of FIG. 22, the CPU 30 measures the output voltage v_{bat} of the battery 2 for a fixed period of time, and obtains and retains the maximum value Vₘₐₓ and the minimum value Vₘᵢₙ of the output voltage v_{bat} as digital values.

Then, in Step S502, the CPU 30 derives the average Vₐᵥₑ of the output voltage v_{bat} of the battery 2. In the embodiment, the CPU 30 derives the average Vₐᵥₑ by using Equation (4) as described above to calculate the average of the maximum value Vₘₐₓ and the minimum value Vₘᵢₙ of the output voltage v_{bat}.

Then, in Step S504, the CPU 30 sets the output voltage V_{dac} of the DAC 22. In the embodiment, the output voltage V_{dac} of the DAC 22 is set to be the same as the average Vₐᵥₑ of the output voltage v_{bat} of the battery 2.

Then, in Step S506, the CPU 30 starts the output of the output voltage V_{dac} from the DAC 22. When the process of Step S506 is completed, the subtraction unit adjustment process shown in FIG. 22 is completed. Through the subtraction unit adjustment process, the subtraction amount from the output voltage v_{bat} output from the battery 2 is adjusted in the subtraction unit 13.

In the embodiment, the voltage detection device 10 including the subtraction unit 13 and the amplification unit 15 is described as an example of a circuit having two functions, i.e., subtraction and amplification, but the disclosure is not limited to the configuration. For example, the configuration may include a single circuit having two functions, i.e., subtraction and amplification. A specific example in this case includes a differential amplification unit.

As described above, the voltage detection device 10 of the first and second embodiments is a voltage detection device that measures the output voltage of the battery 2 by using the ADC 20. The voltage detection device 10 includes the multiplication-and-division unit 12 or the subtraction unit 13, which functions as a level shift unit that shifts the voltage level of the voltage signal output from the battery 2 to the median of the measurement range of the ADC 20. The voltage detection device 10 also includes the amplification unit 14 or the amplification unit 15 that amplifies the voltage signal in which the voltage level has been shifted by the multiplication-and-division unit 12 or the subtraction unit 13. Additionally, the voltage detection device 10 includes the ADC 20 that measures the voltage signal amplified by the amplification unit 14 or the amplification unit 15 and outputs a digital sample signal corresponding to the voltage signal. The voltage detection device 10 also includes the microcontroller 16 containing the CPU 30 that derives the voltage value of the output voltage of the battery 2 based on the sample signal output from the ADC 20.

For example, unlike the voltage detection device 10 of the embodiment, in a case where a battery is connected to an ADC and the output voltage v_{bat} of the battery is directly detected by the ADC, if the resolution of the ADC is low, among the changes of the output voltage v_{bat}, for small changes (amplitudes) over a short period of time corresponding to the load connected to the battery may be rounded to a constant digital value and cannot be detected. On the other hand, if the resolution of the ADC is increased to detect small changes (amplitudes), the cost may increase. Additionally, if the measurement range of the ADC is widened to detect large changes over a long period of time, the measurement values of small changes over a short period of time become coarse. Moreover, during the measurement of small changes over a short period of time, only a portion of the measurement range of the ADC is used. Therefore, most of the measurement range remains unused, and the performance cannot be fully utilized. Meanwhile, if the measurement range of the ADC is reduced to detect small changes over a short period of time, the circumstances such as the time of full charge or the time immediately before complete discharge may fall outside the measurement range of the ADC, for example, and large changes over a long period of time may not be detectable.

Comparatively, the voltage detection device 10 of the first and second embodiments, with the configurations described above, can measure the output voltage of the battery 2 within the measurement range of the ADC 20 regardless of the output voltage of the battery as well as the magnitude of the amplitude. Therefore, it can accurately detect both long-term changes and short-term changes in the output voltage of the battery.

While the amplification unit 14 of the first embodiment and the amplification unit 15 of the second embodiment are described as a non-inverting amplification unit in the above description, an inverting amplification unit may also be adopted in accordance with the properties of voltage changes. In the case where an inverting amplification unit is adopted, the sample value measured by the ADC 20 from the output of the amplification unit 14 or the amplification unit 15 is an inverted value of the actual output voltage v_{bat} of the battery 2. Therefore, the output voltage v_{bat} of the battery 2 can be derived by performing calculation that takes into account the inversion of the value.

Furthermore, while the first embodiment describes adjusting the multiplication-and-division unit 12 by using the output of the DAC 22 and the second embodiment describes adjusting the subtraction unit 13 by using the output of the DAC 22, the adjustment of the multiplication-and-division unit 12 or the subtraction unit 13 may also be performed by means other than the DAC 22. As an alternative to the DAC 22, for example, a means capable of generating an arbitrary voltage can be used.

In addition, in the first embodiment, a variable resistor other than an analog photocoupler may be used as the variable resistor 106 of the amplification unit 14. For example, a variable resistor in which the resistance value is controlled by a switch may also be used. In the case where a variable resistor in which the resistance controlled by a switch is used, to control the resistance value, a DAC or a general-purpose input/output (GPIO) may be used as appropriate in place of the PWM 24, depending on the type of the resistor. In the case of using a DAC for resistance value control, it is necessary to prepare a separate channel from the DAC 22. Furthermore, in the case where a variable resistor other than an analog photocoupler, the resistor 100 may not be necessary.

Several appendices are further disclosed in the following in relation to the above embodiments.

### Appendix 1

A voltage detection device, measuring a voltage of a battery by using an analog-to-digital converter (ADC). The voltage detection device includes: a level shift unit, shifting a voltage level of a voltage signal output from the battery to a median of a measurement range of the ADC; an amplification unit, amplifying the voltage signal in which the voltage level is shifted by the level shift unit; the ADC, measuring the voltage signal amplified by the amplification unit, and outputting a digital sample signal in accordance with the voltage signal; and a derivation unit, deriving a voltage value of a voltage of the battery based on the sample signal output from the ADC.

### Appendix 2

In the voltage detection device according to Appendix 1, the level shift unit includes a multiplication-and-division unit performing multiplication or division on the voltage value of the voltage signal output from the battery.

### Appendix 3

In the voltage detection device according to Appendix 1, the level shift unit includes: a subtraction unit, performing subtraction from the voltage value of the voltage signal output from the battery.

### Appendix 4

In the voltage detection device according to Appendix 1, the level shift unit and the amplification unit are formed by one circuit.

### Appendix 5

In the voltage detection device according to Appendix 4, the circuit shifts the voltage level of the voltage signal by performing subtraction from the voltage value of the voltage signal output from the battery.

### Appendix 6

In the voltage detection device according to Appendix 1, an amplification degree of the amplification unit is arranged to be variable.

### Appendix 7

In the voltage detection device according to Appendix 1, an amplification degree of the amplification unit is arranged to be fixed.

### Appendix 8

In a voltage detection method, a processor included in a voltage detection device that measures a voltage of a battery by using an analog-to-digital converter (ADC) is configured to: shift, by using a level shift unit, a voltage level of a voltage signal output from the battery to a median of a measurement range of the ADC; amplify, by using an amplification unit, the voltage signal in which the voltage level is shifted by the level shift unit; measure, by using the ADC, the voltage signal amplified by the amplification unit, and outputting a digital sample signal in accordance with the voltage signal; and derive a voltage value of a voltage of the battery based on the sample signal output from the ADC.

### Appendix 9

In a voltage detection program, a processor included in a voltage detection device that measures a voltage of a battery by using an analog-to-digital converter (ADC) is arranged to: shift, by using a level shift unit, a voltage level of a voltage signal output from the battery to a median of a measurement range of the ADC; amplify, by using an amplification unit, the voltage signal in which the voltage level is shifted by the level shift unit; measure, by using the ADC, the voltage signal amplified by the amplification unit, and outputting a digital sample signal in accordance with the voltage signal; and derive a voltage value of a voltage of the battery based on the sample signal output from the ADC.

What is claimed is:

1. A voltage detection device, measuring a voltage of a battery by using an analog-to-digital converter (ADC), the voltage detection device comprising:
a level shift unit, shifting a voltage level of a voltage signal output from the battery to a median of a measurement range of the ADC;
an amplification unit, amplifying the voltage signal in which the voltage level is shifted by the level shift unit;
the ADC, measuring the voltage signal amplified by the amplification unit, and outputting a digital sample signal in accordance with the voltage signal; and
a derivation unit, deriving a voltage value of a voltage of the battery based on the sample signal output from the ADC.

2. The voltage detection device as claimed in claim 1, wherein the level shift unit comprises a multiplication-and-division unit, performing multiplication or division on the voltage value of the voltage signal output from the battery.

3. The voltage detection device as claimed in claim 1, wherein the level shift unit comprises:
a subtraction unit, performing subtraction from the voltage value of the voltage signal output from the battery.

4. The voltage detection device as claimed in claim 1, wherein the level shift unit and the amplification unit are formed by one circuit.

5. The voltage detection device as claimed in claim 4, wherein the circuit shifts the voltage level of the voltage signal by performing subtraction from the voltage value of the voltage signal output from the battery.

6. The voltage detection device as claimed in claim 1, wherein an amplification degree of the amplification unit is arranged to be variable.

7. The voltage detection device as claimed in claim 1, wherein an amplification degree of the amplification unit is arranged to be fixed.

8. A voltage detection method, wherein a processor comprised in a voltage detection device that measures a voltage of a battery by using an analog-to-digital converter (ADC) is configured to:
shift, by using a level shift unit, a voltage level of a voltage signal output from the battery to a median of a measurement range of the ADC;
amplify, by using an amplification unit, the voltage signal in which the voltage level is shifted by the level shift unit;
measure, by using the ADC, the voltage signal amplified by the amplification unit, and outputting a digital sample signal in accordance with the voltage signal; and
derive a voltage value of a voltage of the battery based on the sample signal output from the ADC.
